(19) United States
(12) Patent Application Publication
(10) Pub. No.: US 2008/0009353 A1
(43) Pub. Date: Jan. 10, 2008

(54) Gaming Machine Electronics Enclosure

(76) Inventors: Vladimir Halic, Lane Cove (AU); Robert Liniey Muir, Lane Cove (AU); Roman Seifert, Lane Cove (AU)

Correspondence Address: MCANDREWS HELD & MALLOY, LTD, 500 WEST MADISON STREET, SUITE 3400, CHICAGO, IL, 60661, US

(21) Appl. No.: 10/568,196

(22) PCT Filed: Aug. 2, 2004
(86) PCT No.: PCT/AU04/01027

§ 371 Date: May 3, 2007

(30) Foreign Application Priority Data
Aug. 11, 2003 (AU) 2003904255

(51) Int. Cl. H05K 5/00; A63F 13/08

(52) U.S. Cl. 463/46; 361/725

(57) ABSTRACT

A gaming machine electronics enclosure includes a box-shaped structure comprised of a plurality of members enclosing a volume, the structure further defining an access opening. The enclosure includes a lid for closing off the access opening, the lid being lockable with respect to the structure in a position closing off the opening for securing components contained within the volume. At least one of the members is displaceably arranged relative to the remainder of the members at least when the lid is in an open configuration for facilitating access to an interior of the structure.

### FIELD OF THE INVENTION

This invention relates to a gaming machine. More particularly, the invention relates to a gaming machine electronics enclosure.

### BACKGROUND OF THE INVENTION

With the growth that has occurred in the gaming machine market, there is intense competition between manufacturers to supply various existing and new venues. When selecting a supplier of gaming machines, the operator of a venue will pay close attention to the various options a machine may have including, for example, the game played on the machine, the level of maintenance required and the ease of serviceability.

Many venues operate continuously and, as a result, require that the gaming machines are in operation for the majority of this time. Therefore, gaming machine manufacturers are keen to devise gaming machines that have easy access to the parts of the gaming machine requiring maintenance and, in particular, the parts of the gaming machine housing the electronic equipment, yet provide a required level of security to inhibit unauthorised access to these areas.

The electronic boards used in gaming machines are plugged into a backplane of an electronics housing in the gaming machine. To service the electronic boards, the boards are pushed into or pulled out of the backplane. However, there is a trend to using standard PC motherboards. These motherboards are not designed to fit a backplane.

### SUMMARY OF THE INVENTION

According to a first aspect of the invention, there is provided a gaming machine electronics enclosure which includes:
a box-shaped structure comprised of a plurality of members enclosing a volume, the structure further defining an access opening;
a lid carried by one of the members for closing off the access opening for securing components contained within the volume; and
at least one of the members being a displaceable member which is displaceably arranged relative to the remainder of the members so that, when the displaceable member is in a displaced position relative to the remainder of the members, the access opening is enlarged to facilitate access to an interior of the structure.

The box-shaped structure may include a rear member, a pair of opposed side members projecting from the rear member and top and bottom members spanning the side members. The opening may be defined by free edges of the side members, the top member and the bottom member.

The lid may be hingedly secured to the free edge of one of the members, preferably that member opposite the displaceable member.

In a preferred embodiment of the invention, the bottom member is displaceably arranged with respect to the remaining members. Thus, the lid may be hingedly secured to the free edge of the top member. When the lid is open and the bottom member is displaced to its open position, a larger access opening is provided. This facilitates servicing, replacement and/or installation of components in the structure.

Preferably, the bottom member is hingedly secured via opposed hinges to the side members at an operatively rear region of each side member. The hinges may be able to be disassembled for facilitating complete removal of the bottom member from the side members.

The bottom member may carries a motherboard for the gaming machine. Thus, when the bottom member is in its open configuration, access to the motherboard for servicing, inspection and/or replacement is facilitated. As indicated above, the bottom member is able to be removed entirely for servicing and/or replacement of the motherboard.

The bottom member may further include a support member for supporting auxiliary components such as printed circuit boards (PCB's) that may be attached to the motherboard. These auxiliary components may be standard PC components such as, for example, video cards, network communication boards, or the like. The support member may be a bracket which provides secure access for a cable interface.

The enclosure may include a housing for a data storage device. The housing may be suspended from the top member of the structure. The storage device may be a hard disc or a CD ROM drive.

The enclosure may further include a cooling unit. The cooling unit may be arranged below the housing for drawing air over the data storage device and on to the motherboard.

The rear member may act as a backplane for PCB's which plug into the backplane. These PCB's may comprise proprietary boards providing additional gaming related functionality not provided by standard PC assemblies.

The rear member may also carry mounting formations for mounting the structure to a cabinet of the gaming machine in a secure fashion. The mounting formations may be arranged internally of the side members, the top member and the bottom member so that, when the lid is in its closed position and is locked, access to the mounting formations is inhibited.

According to a second aspect of the invention, there is provided a controller for a gaming machine, the controller comprising:
an enclosure having a displaceable member which is displaceably arranged relative to the remainder of the enclosure; and
at least a processor of the controller being carried on the displaceable member of the enclosure.

The processor may encompass standard PC technology.

### BRIEF DESCRIPTION OF THE DRAWINGS

An embodiment of the invention is now described, by way of example, with reference to the accompanying diagrammatic drawings in which:

FIG. 1 shows a perspective view of a gaming machine electronics enclosure, in accordance with an embodiment of the invention, in a closed state;

FIG. 2 shows a perspective view of the enclosure in an open state; and

FIG. 3 shows a perspective view of the enclosure in a disassembled state.

### DETAILED DESCRIPTION OF EXEMPLARY EMBODIMENT

In the drawings, reference numeral 10 generally designates a gaming machine electronics enclosure, in accordance with an embodiment of the invention.

The enclosure 10 includes a box-like structure 12 having a rear member 14, a pair of opposed side members 16 projecting from the rear member 14, a bottom member 18 and a top member 20. The top member 20 spans the side members 16 and also projects from the rear member 14.

As will be described in greater detail below, the bottom member 18 is displaceably arranged relative to the side members 16 and is hingedly secured to the side members 16.

The side members 16, the top member 20 and the bottom member 18, when the bottom member 18 is in its closed configuration, defines an access opening 22. The access opening 22 is closed off by a lid 24. The lid 24 is secured via a hinge 26 to a free edge of the top member 20.

The lid 24 carries a lock 28 and, when in its closed configuration, as shown in FIG. 1 of the drawings, and the bottom member 18 is similarly in its closed configuration, locks to a locking formation 30 carried proximate a front edge of the bottom member 18 securely to enclose a volume 32 defined by the structure 12 and the lid 24.

The component parts of the structure 12, being the rear member 14, the side members 16, the bottom 18 and the top member 20 as well as the lid 24 are of sheet metal construction for inhibiting access being gained to the interior of the structure 12 when the lid 24 is in its closed, locked configuration.

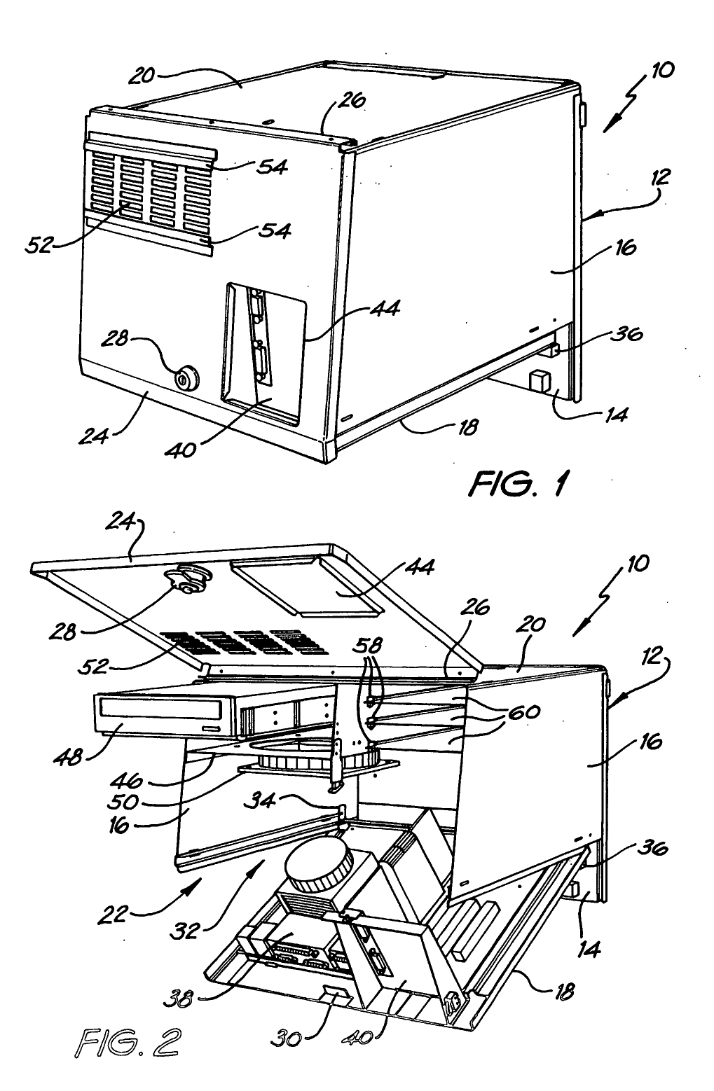

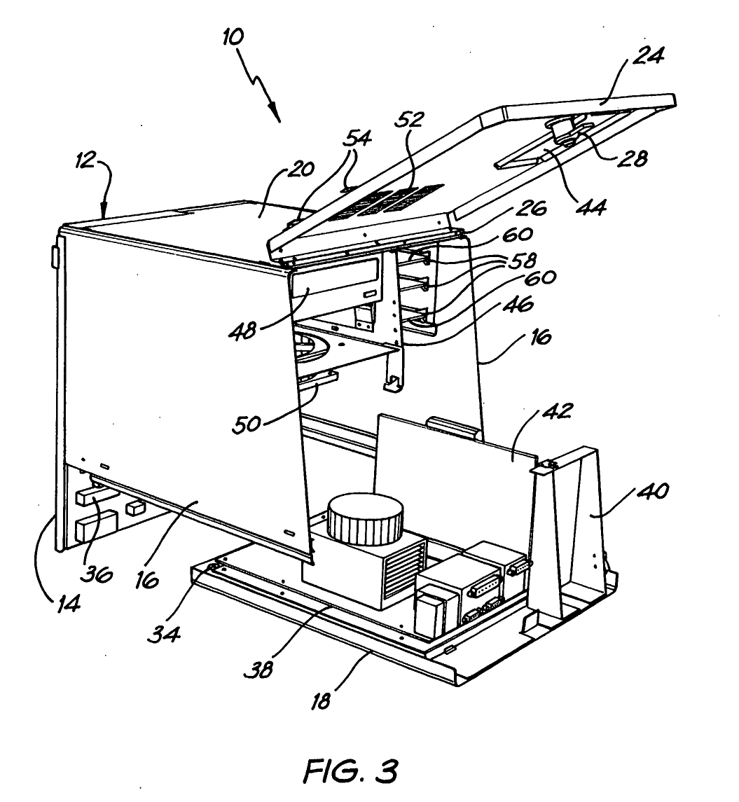

The bottom member 18 is hingedly secured via a pair of opposed hinges 34, one of which is shown in FIG. 2 of the drawings, to rear regions of the side members 16 to be able to pivot between the closed configuration as shown in FIG. 1 of the drawings and an open configuration as shown in FIG. 2 of the drawings. It is to be noted that the rear member 14 carries stop members 36 for limiting the degree of downward pivoting of the bottom member 18 relative to the side members 16. In addition, the hinges 34 are configured such that, by lifting the rear part of the bottom member 18 relative to the side members 16, the hinges 34 can be disengaged from the side members 16 to facilitate removal of the bottom member 18 from the remainder of the structure 12, as shown in FIG. 3 of the drawings.

The bottom member 18 supports a motherboard 38 of the gaming machine. The bottom member 18 further carries a support member in the form of a support bracket 40. The support bracket 40 supports additional printed circuit boards (PCB's), one of which is shown at 42 in FIG. 3 of the drawings. In addition, the support bracket 40 provides secure access for a cable interface via an opening 44 in the lid 24. The motherboard uses standard PC technology. For example, the technology used is based on a standard ATX and/or UATX PC mechanical specification. This has the benefit that the gaming machine 10 is easily able to be upgraded to take into account the latest technologies and/or to upgrade performance of the gaming machine 10.

A housing 46 for a data storage device 48 is arranged within the structure 12. Preferably, the housing 46 is suspended from the top member 20 and is secured to an internal surface of one of the side members 16. The data storage device 48 is, for example, a hard disc or a CD ROM-drive.

A cooling unit in the form of a cooling fan 50 is arranged below the housing 46. The fan 50 draws air in through slots 52 defined in the lid 24. Air drawn in by the fan 50 is drawn over the device 48 and is then blown on to the motherboard 38 to effect cooling of the device 48 and the motherboard 38.

It is to be noted in FIG. 1 of the drawings that runners 54 are defined on an exterior surface of the lid 24 for supporting a screen of filter media (not shown).

The interior of the structure 12 includes runners 58 (FIG. 3) for additional, auxiliary PCB's 60 which slide along the runners 58 to plug into a backplane defined by the rear member 48.

In use, the enclosure 10 is mounted via suitable fasteners (not shown) to the appropriate formation in the gaming machine. The fasteners extend through the rear member 14 to secure the enclosure 10 in position. Because the fasteners are contained within the interior of the structure, unauthorised access to the fasteners is inhibited when the lid 24 is in its closed, locked configuration. Critical and related electronic components of the gaming machine are arranged within the interior of the structure 12 of the enclosure 10. Critical electronic components of the gaming machine are those which require regulatory approval and which may not be tampered with. The bottom member 18 is retained in its closed position as shown in FIG. 1 of the drawings. The lid 24 is closed and locked to inhibit unauthorised access to the interior of the enclosure 10.

When it is desired to service, inspect, install, repair and/or replace components of the gaming machine, the lid 24 is unlocked and is pivoted about the hinge 26 to the position shown in FIG. 2 of the drawings. The access opening 22 is enlarged by pivoting the bottom member 18 downwardly as shown in FIG. 2 of the drawings to enable easier access to be gained to the required components of the gaming machine contained within the enclosure 10.

It will be appreciated that, in many instances, a technician will be working on the gaming machine under poor lighting conditions. Also, the interior of a cabinet of the gaming machine in which the enclosure 10 is installed contains many other pieces of equipment and, as such, is a very confined space within which to work. By having the bottom member 18 fully detachable from the remainder of the structure 10, the technician's task is facilitated and the bottom member 18 can be removed from the interior of the gaming machine to enable the motherboard to be serviced, etc.

Accordingly, it is an advantage of the invention that an enclosure 10 is provided which improves accessibility to components of the gaming machine by authorised personnel. In addition, when it is desired to replace the motherboard 38, this can be facilitated easily by removal of the bottom member 18 of the enclosure 10. It will be appreciated that it may be desired to replace the motherboard 38 when the gaming machine is refurbished, upgraded or when the gaming machine has its game replaced. When the enclosure 10 is in a closed condition, the critical electronic components of the gaming machine are secured within the interior of the enclosure 10 and unauthorised access to such components is inhibited. The use of steel plate for the members of the structure 12 and lid 24 of the enclosure 10 further inhibits unauthorised access to the components and/or tampering with such components.

Further, it is an advantage of the invention that the combined use of standard PC technology on the motherboard 38 and the hinged enclosure 10 provides a useful solution to the need for ease of manufacture and service of a controller of the gaming machine in a very affordable and cost-effective manner. It is also space-efficient which is advantageous when considering the lack of space in the interior of the gaming machine.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A gaming machine electronics enclosure comprising:
a box-shaped structure comprised of a plurality of members enclosing a volume, the structure defining an access opening; and
a lid carried by one of the members for closing off the access opening, thereby securing components contained within the volume, in which at least one of the members is a displaceable member which is displaceably arranged relative to the remainder of the members so that, when the displaceable member is in a displaced position relative to the remainder of the members, the access opening is enlarged to facilitate access to an interior of the structure.

2. The enclosure as claimed in claim 1 in which the box-shaped structure includes a rear member, a pair of opposed side members projecting from the rear member and top and bottom members spanning the side members.

3. The enclosure as claimed in claim 2 in which the opening is defined by free edges of the side members, the top member and the bottom member.

4. The enclosure as claimed in claim 3 in which the lid is hingedly secured to the free edge of one of the members.

5. The enclosure as claimed in claim 3 in which the lid is hingedly secured to the free edge of one of the members which is opposite the displaceable member.

6. The enclosure as claimed in claim 3 in which the lid is hingedly secured to the free edge of the top member.

7. The enclosure as claimed in claim 2 in which the bottom member is the displaceable member.

8. The enclosure as claimed in claim 2 in which the displaceable member is the bottom member and is hingedly secured via opposed hinges to the side members at an operatively rear region of each side member.

9. The enclosure as claimed in claim 8 in which the hinges are able to be disassembled for facilitating complete removal of the displaceable member from the box-shaped structure.

10. The enclosure as claimed in claim 1 in which the displaceable member carries a motherboard for the gaming machine.

11. The enclosure as claimed in claim 10 in which the displaceable member includes a support member for supporting auxiliary components attached to the motherboard.

12. The enclosure as claimed in claim 11 in which the support member is a bracket which provides secure access for a cable interface.

13. The enclosure as claimed in claim 2 which includes a housing for a data storage device.

14. The enclosure as claimed in claim 13 in which the housing is suspended from the top member of the structure.

15. The enclosure as claimed in claim 13 which includes a cooling unit.

16. The enclosure as claimed in claim 15 in which the cooling unit is arranged below the housing.

17. The enclosure as claimed in claim 2 in which the rear member acts as a backplane for printed circuit boards which plug into the backplane.

18. The enclosure as claimed in claim 2 in which the rear member carries mounting formations for mounting the structure to a cabinet of the gaming machine in a secure fashion.

19. The enclosure as claimed in claim 18 in which the mounting formations are arranged internally of the side members, the top member and the bottom member.

20. A controller for a gaming machine, the controller comprising:
an enclosure having a displaceable member which is displaceably arranged relative to the remainder of the enclosure; and
at least a processor of the controller being carried on the displaceable member of the enclosure.

21. (canceled)

22. The controller as claimed in claim 20 in which the enclosure further comprises an access opening and when the displaceable member is in a displaced position the access opening is enlarged to facilitate access to an interior of the enclosure.

23. The enclosure as claimed in claim 2 in which the displaceable member is hingedly secured via opposed hinges to the box-shaped structure.

24. The enclosure as claimed in claim 23 in which the hinges are able to be disassembled for facilitating complete removal of the displaceable member from the box-shaped structure.
